(19) United States
(12) Patent Application Publication
(10) Pub. No.: US 2008/0202431 A1
(43) Pub. Date: Aug. 28, 2008

(54) Compact Modular Unit and a Milking Stall Comprising Such a Compact Modular Unit

(75) Inventors: Helmut Obermuller, Stockholm (SE); Lars-Arne Axelsson, Skarpnack (SE)

Correspondence Address: HOVEY WILLIAMS LLP, 10801 Mastin Blvd., Suite 1000, Overland Park, KS, 66210, US

(73) Assignee: DELAVAL HOLDING AB, Tumba (SE)

(21) Appl. No.: 11/722,681

(22) PCT Filed: Dec. 16, 2005
(86) PCT No.: PCT/SE2005/001952

§ 371 Date: Jun. 22, 2007

(30) Foreign Application Priority Data
Dec. 22, 2004 (SE) 0403131-6

(51) Int. Cl. A01J 7/00; H05K 5/00; A01K 1/12

(52) U.S. Cl. 119/14.03

(57) ABSTRACT

The invention relates to a compact modular unit to be mounted in a milking stall having at least one pipeline system, which provides an operative function in connection with a milking process of an animal in the milking stall. The compact modular unit (4) includes a casing (28), which defines an inner space of the compact modular unit (4), an electric control unit (23), which is mounted in the inner space of the compact modular unit (4), and an indicator (27, 50), which is arranged to display information related to the milking processes in the milking stall. Furthermore, the compact modular unit (4) includes a component (9, 10, 17, 52) of the pipeline system which is mounted in the inner space of the compact modular unit (4).

### BACKGROUND OF THE INVENTION AND PRIOR ART

The present invention relates to a compact modular unit to be mounted in a milking stall, wherein the milking stall comprises at least one pipeline system, which provides an operative function in connection with a milking process of an animal in the milking stall and wherein the compact modular unit comprises a casing, which defines an inner space of the compact modular unit, an electric control unit, which is mounted in said inner space of the compact modular unit, and indication means arranged to display information related to a milking process in the milking stall.

Usually, the milking equipment used in a milking stall comprises a number of pipeline systems, which provide different functions in connection with a milking process of an animal in the milking stall. Such a pipeline system is a milk pipeline system, which has the function to transport the milk from the animal, which is milked in the milking stall, to a milk-collecting container. A further pipeline system is a vacuum pipeline system, which has the function to supply a pulsating vacuum to a milking member, which is attached to an animal during the milking process. A further pipeline system is a wash pipeline system, which has the function to transport a cleaning liquid to the milking member and suitable parts of the milk pipeline system, for example, between two milking processes in the milking stall. The pipeline systems are controlled by means of an electric control unit, which controls at least one component in the respective pipeline systems. The electric control unit also may have the function to control other components in the milking stall such as a remover, which removes the milking member from an animal after that a milking process is finished.

It is known to arrange the electric control unit in a so-called milk point controller. The milk point controller comprises a casing, which encases the electric components of the electric control. Further, the milk point controller is provided with a display screen, which may disclose data related to the specific animal, which is milked in the milking stall, and data related to a prevailing milking process in the milking stall. Furthermore, the milking point controller comprises a plurality of push buttons by which it is possible for a milking operator to, for example, control start and stop of the milking process and select information to be disclosed on the display screen. The milk point controller is mounted at a relatively high level in the milking stall in order to give the electric components a protected position in the milking stall.

The components of the respective pipeline systems, which are controlled by the electric control unit, are mounted in substantially arbitrary positions in different milking stall. Such components are, for example, a milk meter of the milk pipeline system, a pulsator of the vacuum pipeline system and a control valve of the wash pipeline system. The length and the direction of the tubes in the respective pipeline systems, which are connected to said components, depend on, for example, the mounting position of said components in the milking stall. Therefore, the mounting work of the tubes in the respective pipeline systems is relatively time consuming. Furthermore, relatively long electric cables have to be arranged between the milking point controller, which is positioned at a relatively high level in the milking stall, and said components, which are mounted in substantially arbitrary position in the milking stall. Therefore, the mounting work of the electric cables also is relatively time consuming. Furthermore, services and exchange of defective components are relatively complicated due to the unlike mounting of the milking equipment in different milking stalls.

### SUMMARY OF THE INVENTION

The object of the present invention is to provide milking equipment in a milking stall, which enables an uncomplicated mounting work, a simple service work and an easy exchange of defective components of the milking equipment.

These objects are obtained according to the invention by the feature that the compact modular unit comprises said component of the pipeline system, which is mounted in the inner space of the compact modular unit. Such a compact modular unit may be mounted in an uncomplicated manner as an integrated unit in different kinds of milking stalls. The electric control unit and said component mounted inside the compact modular unit may have a standardized design. Thereby, it is very easy to exchange a defective electric control unit and such a component. Furthermore, the compact modular unit may comprise a plurality of other parts in the inner space such as electric signal lines, which are arranged between the electric control unit and the components, and short tubular elements of the pipe line system, which are connected to said component. Such parts may also have a standardized length and design. Thereby, it is also easy to exchange such defective parts. It is customary to perform services of the milking equipment with predetermined intervals. During such services, it is normally to exchange certain parts of the milking equipment especially parts, which are in contact with milk. Due to the standardized design of the parts inside the compact modular unit, it is easy for a serviceman to be provided with a kit of such parts, which have to be exchanged. The kit may comprise short tubular elements and gaskets, which are in contact with milk in the inner space of the compact modular unit.

According to a preferred embodiment of the invention, said pipeline system is a milk pipeline system arranged to transport milk in the milking stall. Advantageously, the component of said milk pipeline system, which is mounted in said inner space of the compact modular unit, is a milk meter. An electric signal line between the milk meter and the electric control unit inside the compact modular unit may be a short electric line of a standardized length. The electric control unit may control the milk meter such that it measures and sends information about the milk flow in the milk pipeline system during the milking processes in the milking stall. Thereby, the electric control unit may calculate the total milk quantity, which is obtained from each milking process in the milking stall. Furthermore, the milk flow during different milking periods may be analyzed, for example, in the milk meter. It is also possible to extract a milk sample and transport it to an external analyzing device. The compact modular unit may comprise connection means, which enables a releasable connection of at least one milk tube to the compact modular unit. Such connection means may comprise two nipples of suitable dimensions such that it is possible to connect an inlet milk tube and an outlet milk tube to the compact modular unit. Furthermore, short tubular elements may be arranged in the inner space of the compact modular unit in order to constitute a connection between the nipples and the milk meter. Preferably, the milk meter is calibrated before it is mounted in the inner space of the compact modular unit.

According to a further embodiment of the invention, said pipeline system is a vacuum pipeline system arranged to supply a pulsating pressure to a milking member, which is attached to an animal during a milking process in the milking stall. Such a milking member may be a cluster with a claw and four teatcups, which are connected by four short milk tubes. The milking member may also be constituted by a teat cup. The component of said vacuum pipeline system, which is mounted in the inner space of the compact modular unit, may be a pulsator. An electric signal line between the pulsator and the electric control unit inside the compact modular unit may be relatively short and standardized. Furthermore, the pulsator achieves a protected placing in the milking stall and the noise, which the pulsator generates during work to the surrounding, will be remarkably reduced. The compact modular unit comprises connection means, which enables a releasable connection of at least one pulse tube of the vacuum pipeline system to the compact modular unit. The connection means may comprise a nipple of a dimension such that it is easy to connect a pulse tube to the compact modular unit. When a cluster is used, two pulse tubes are normally arranged between the compact modular unit and the claw of the cluster. The pulsator may supply pulsating vacuums with a certain phase displacement to the respective pulse tubes. Preferably, the compact modular unit comprises connection means, which enables a releasable connection of a vacuum tube of the vacuum pipeline system to the compact modular unit. Thereby, the pulsator may be controlled such that it alternatively connects the two pulse tubes to the vacuum tube. Preferably, the compact modular unit comprises connection means, which enables a releasable connection of a fresh air tube of the vacuum pipeline system to the compact modular unit. Thereby, the pulsator may be controlled such that it alternatively connects the two pulse tubes to the fresh air tube. The component of said vacuum pipeline system, which is mounted in the inner space of the compact modular unit, may be a valve arrangement arranged to control the vacuum level supplied to the milking member. The vacuum level is controlled by signals from the electric control unit via an electric signal line arranged inside the compact modular unit.

According to a further embodiment of the invention, said pipeline system is a wash pipeline system arranged to wash a milking member. Such a wash pipeline system may comprise a washing assembly, which comprises a manifold and four candle-shaped plugs to which the teatcups of a cluster may be attached during a washing process. Advantageously, the component of said wash pipeline system, which is mounted in the inner space of the compact modular unit, is a control valve. The control valve may be arranged between the washing assembly and a main pipeline in which the cleaning liquid is stored with an overpressure. When the control valve is open, the cleaning liquid flows to the washing assembly. The cleaning liquid flows, via the four candle-shaped plugs of the washing assembly, to the inner spaces of the teat cups and suitable parts of the milk pipeline system. An electric signal line between the control valve and the electric control unit in the inner space of the compact modular unit may be short and standardized. Furthermore, the control valve achieves a protected placing in the milking stall. The compact modular unit may comprise connection means, which enables a releasable connection of at least one cleaning liquid tube to the compact module unit. Preferably, the connection means comprises two nipples of suitable dimension such that it is possible to connect an inlet cleaning liquid tube and an outlet cleaning liquid tube to the compact modular unit. Thereby, it is possible to achieve a cleaning liquid flow through the compact modular unit when the control valve is open.

According to a further embodiment of the invention, the compact modular unit comprises connection means, which enables a connection of an electric signal line to the compact modular unit. Thereby, it is possible to achieve a communication between, for example, a main control system for a plurality of milking stalls and the electric control unit in an individual milking stall. The main control system may, for example, provide the electric control system in the individual milking stalls with information about the identity of the animals, which enter the milking stalls. The electric control units for the individual milking stalls may provide the main control system with information about the milk quantity from each milking process in the milking stall. Furthermore, the compact modular unit may comprise connection means, which enables a releasable connection of an electric cable to the compact modular unit, which is connected to an electric power source. Thereby, a required supply of electric power to the electric control unit is achieved. Said connection means may be an electric coupling device, which enables a quick and simple connection of an end part of the electric cable.

According to a preferred embodiment of the invention, said electric control unit is arranged to control a remover, which is arranged to remove a cluster from an animal after a milking process is finished. When a milking process is finished, the electric control unit sends a control signal to the remover, which initiates the removing motion of the remover. Preferably, the compact modular unit comprises connection means, which enables a releasable connection of an electric signal line from the remover to the compact modular unit. Said connection means may be an electric coupling device, which enables a quick and simple connection of an end part of the electric signal line from the remover.

According to a preferred embodiment of the invention, the casing has a construction such that said inner space is substantially hermetically encased. Thereby, the risk that unclean air is sucked into the inner space of the compact modular unit is substantially eliminated. The compact modular unit may comprise a body, which encases the electric control unit in the inner space of the compact modular unit. Electric components are very sensitive for corrosive substances and impurities. In this case, the electric components of the electric control unit are encased in a body, which is encased in the inner space of the casing. Even if damp penetrates through the casing of the compact modular unit, the electric components of the electric control unit are well protected from the damp inside said body. Consequently, the electric components have a very protected placing in the compact modular unit. The body, which encases the electric control unit, may comprise a transparent plastic material. The fresh air tube may be connected to an inner space of said body. Thereby, it is guaranteed that the electric components inside the body are in contact with fresh air.

According to a preferred embodiment of the invention, the electric control unit is mounted in a position in the inner space of the compact modular at a distance from the inner surfaces of the walls of the casing, which outer surfaces are in contact with the surrounding air in the milking stall. Such a positioning of the electric control unit and preferably the other components in the inner space of the compact modular unit reduces the risk of damages caused by external forces acting on the outer wall surfaces of the casing. Furthermore, the air gap between the electric control unit and said inner walls of the casing provides a heat insolating layer, which protects the electric control units from rapid temperature changes.

According to a preferred embodiment of the invention, said indicating means comprises at least one indicating lamp. Preferably, the compact modular unit comprises a plurality of indicating lamps, which inform a milking operator of different operation conditions of a prevailing milking process in the milking stall. Furthermore, said indicating means may comprise an indicating screen. Such a screen may display information for the milking operator by means of words, icons or graphic representation. Advantageously, the compact modular unit comprises a manual control member. Thereby, it is possible for a milking operator to manually control at least one function in connection with a milking process. Such a function may be the start and the stop of a milking process. The manual control member may be a push button. Preferably, such a push button has a construction such that damp and impurities from the surrounding air do not have possibility to penetrate into the inner space of the compact modular unit.

According to a preferred embodiment of the invention, the electric control unit and said component are pre-mounted in the inner space of the compact modular unit before the compact modular unit is mounted in the milking stall. Preferably, all components and parts are pre-mounted in the inner space of the compact modular unit. By the use of such a compact modular unit, a large number of components and parts will be mounted as an integrated unit in a quick and simple manner in a milking stall.

The invention also relates to a milking stall comprising such a compact modular unit. The milking stall may comprise a floor surface for the animal to stand on during the milking process and a pit located adjacent to said floor surface. The compact modular unit may be mounted in the pit at a level below the floor surface of the milking stall. Due to the protected placing of the electric control unit in the inner space of the casing, it is possible to mount the compact modular unit in the hard environment, which prevails in a pit of a milking stall. The compact modular unit may be mounted against a wall surface of the pit. It may be mounted direct against the wall surface or by means of a suitable holding member. Preferably, the pit comprises an overhang at an upper edge, wherein the compact modular unit is mounted in a position under said overhang. In such a position, the compact modular unit is guaranteed protected from damages, which may be caused by the animals in the milking stall. We overhang may comprise such a holding member which allows a simple mounting of the compact modular unit.

### BRIEF DESCRIPTION OF THE DRAWINGS

In the following, preferred embodiments of the invention are described by examples and with references to the attached drawings, in which

FIG. 1 shows a side view of a part of a milking stall equipped with a compact modular unit according to the invention,

FIG. 2 shows a front view of a compact modular unit and connected milking equipment in a milking stall,

FIG. 3 shows, more in detail, a first embodiment of the compact modular unit,

FIG. 4 shows schematically the components and parts, which are mounted, in the inner space of the compact modular unit in FIG. 3,

FIG. 5 shows a second embodiment of the compact modular unit and

FIG. 6 shows schematically the components and parts, which are mounted, in the inner space of the compact modular unit in FIG. 5.

### BRIEF DESCRIPTION OF PREFERRED EMBODIMENTS OF THE INVENTION

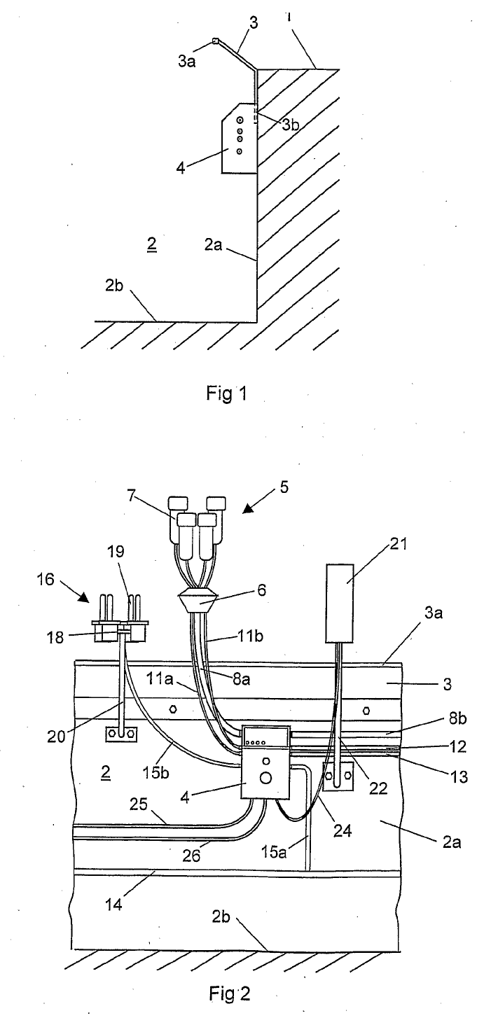

FIG. 1 shows a part of a milking stall. The milking stall comprises a floor surface 1 for cows to stand on during a milking process in the milking stall. A pit 2 is arranged in the milking stall adjacent to the floor surface 1. The pit 2 comprises a substantially vertical wall surface 2a, which at an upper end is connected to the floor surface 1 of the milking stall. The pit 2 comprises a floor surface 2b for milking operators to stand on during the work in the milking stall. An overhang 3 is arranged at an upper edge of the wall surface 2a of the pit. The overhang 3 may be a suitably shaped metal sheet provided with a stabilizing outer edge 3a. A box-shaped compact modular unit 4 is mounted against the wall surface 2a of the pit at a level below the floor surface 1 of the milking stall. The compact modular unit 4 is mounted in a position under the overhang 3. Thereby, the compact modular unit 4 is protected from damages caused by the cows, for examples, by kicks. In this case, a lower part of the overhang 3 comprises holding member 3b. The holding member 3b makes the mounting of the compact modular unit 4 to the wall surface 2a very simple.

FIG. 2 shows a front view of the compact modular unit 4 in its mounting position in the pit 2 and surrounding milking equipment in the milking stall. The milking equipment comprises a milking member in the form of a cluster 5, which comprises a claw 6 and four teatcups 7 connected to the claw 6 by four short milk tubes and four short pulse tubes. However, the four short pulse tubes have not been indicated in the figure. Further, the milking equipment comprises a milk pipeline system. The milking stall may be one of plural milking stalls, which are arranged along the extension of the pit 2. Thereby, the milk pipeline system in the milking stall may constitute a part of a main milk pipeline system for a plurality of milking stalls. The milk pipeline system has the function to transport the milk from the cow in the milking stall to a milk-collecting container. The milk pipeline system is in a conventionally manner connectable to a vacuum source for this transportation of the milk. The milk pipeline system comprises a first milk tube 8a and a second milk tube 8b. The first milk tube 8a conducts milk from the claw 5 to the compact modular unit 4 and the second the milk tube 8b conducts milk from the compact modular unit 4 towards said milk-collecting container. A milk meter 9, which not is visible in FIG. 2, is mounted in an inner space of the compact modular unit 4. The milk meter 9 has the function to measure the milk flow through the compact modular unit 4.

Further, the milking equipment comprises a vacuum pipeline system, which is arranged to provide a pulsating vacuum to the teatcups 7 during a milking process of an animal. The vacuum pipeline system comprises a pulsator 10. The pulsator 10, which not is visible in FIG. 2, is also mounted in the inner space of the compact modular unit 4. The vacuum pipeline system comprises two long pulse tubes 11a, b which are mounted in parallel between the compact modular unit 4 and the claw 6. Each of the long pulse tubes 11a, b is arranged to supply a pulsating vacuum from the pulsator 10, via the claw 6 and the short pulse tubes, to a pulsating chamber of the respective teatcups 7. In order to provide pulsating vacuums in the long pulse tubes 11a, b, the pulsator 10 is connected to a vacuum source via a vacuum tube 12 and a fresh air source via a fresh air tube 13. The pulsator 10 includes valve members, which connect the long pulse tubes 11a, b alternately to the vacuum source and the fresh air source. Thereby, a pulsating vacuum is arisen in the respective long pulse tubes 11a, b, which is supplied to the respective pairs of teatcups 7. Further, the vacuum pipeline system may comprise a valve arrangement 52; which is arranged to adjust the vacuum level from the vacuum source to a desired value. Such a valve arrangement 52, which not is visible in FIG. 2, may also be mounted in the inner space of the compact modular unit 4.

Further, the milking equipment comprises a wash pipeline system, which has the function to transport a cleaning liquid to the teatcups 7 and the milk tubes 8a, b after a milking process has been finished in the milking stall. The wash pipeline system in the milking stall comprises a part of main pipeline 14, which has an extension along the wall surface 2a of the pit. In the main wash pipeline 14, a cleaning liquid is stored with an overpressure. The wash pipeline system comprises a first cleaning liquid tube 15a and a second cleaning liquid tube 15b. The first cleaning liquid tube 15a has an extension between the main pipeline 14 and the compact modular unit 4. The second cleaning liquid tube 15b has an extension between the compact modular unit 4 and a washing assembly 16. A control valve 17, which is not visible is FIG. 2, is mounted in the inner space of the compact modular unit 4 between the first cleaning liquid tube 15a and the second water tube 15b. The washing assembly 16 comprises a manifold 18, which is connected to the second cleaning liquid tube 15b. Furthermore, the manifold 18 is connected to four candle-shaped plugs 19 to which the teatcups 7 are attached during a washing process. The washing assembly 16 is supported by a first holding member 20, which at a lower part is attached to the wall surface 2a of the pit.

Furthermore, the milking equipment in the milking stall comprises an electric control unit 23, which also is mounted in the inner space of the compact modular unit 4 and not visible in FIG. 2. The electric control unit 23 is arranged to control the whole milking process in the milking stall. Consequently, the electric control unit 23 has the function to control the different systems used in the milking stall, such as the milk pipeline system, the vacuum pipeline system and the wash pipeline system. Furthermore, the electric control unit 23 has the function to control a remover 21, which is schematically shown in FIG. 2. The remover 21 has the function to remove the cluster 5 from the cow when a milking process is finished in the milking stall. The remover 21 is supported by a second holding member 22, which at a lower part is attached to the wall surface 2a of the pit. An electric cable in the form of an electric signal line 24 extends between the compact modular unit 4 and the remover 21. The electric signal line 24 enables the transmission of control signals from the electric control unit 23 to the remover 21. The electric control unit 23 has also the function to communicate with a main control system for a plurality of milking stalls. Therefore, an electric cable in the form of an electric signal line 25 is connected to the compact modular unit 4. Furthermore, the electric control unit 23 is connected to an electric power source via an electric cable 26.

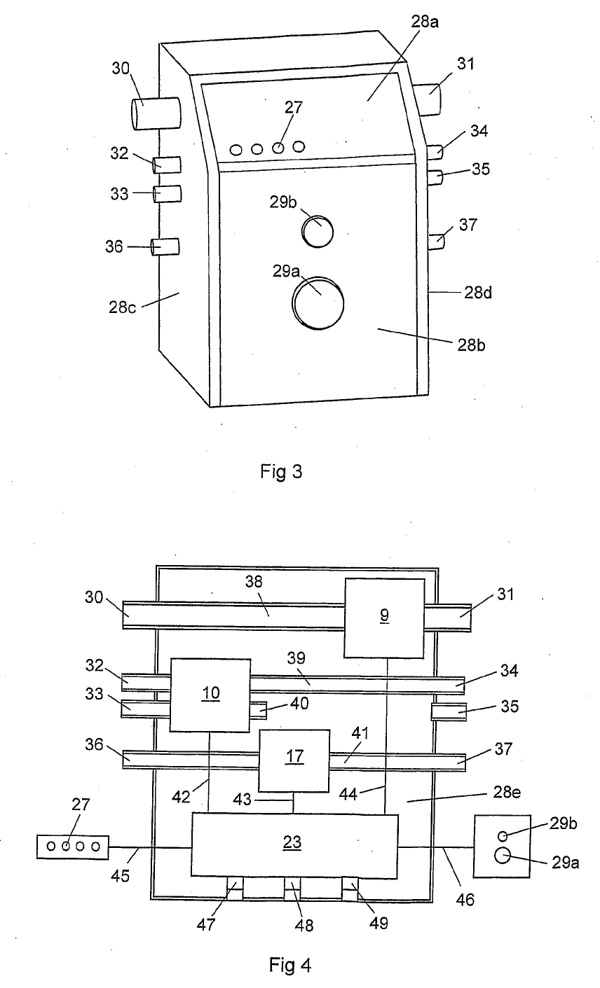

FIG. 3 shows an embodiment of the compact modular unit 4 more in detail. The compact modular unit 4 has a casing 28, which defines the inner space of the compact modular unit 4. The casing 28 is arranged to enclose the components mounted in the inner space substantially hermetically. The casing 28 may be manufactured of stainless steel or a suitable plastic material or a combination of these materials. The casing 28 comprises a front wall surface with an upwards inclined part 28a. Indicating means in the form of four indicating lamps 27 is arranged on the inclined part 28a of the casing. Due to the inclination of the part 28a, the indicating lamps 27 are clear visible for a milking operator standing in the pit 2. The indicating lamps 27 may indicate different operation conditions in the milking stall. Two push buttons 29a, b are arranged at a vertical part 28b of the front wall surface of the casing. A milking operator may use one push button 29a for initiating start and stop of the milking process i.e. to start and stop the pulsator 10. The other push button 29b may be used to initiate start and stop of the washing process, which is performed by the wash pipeline system. The push buttons 29a, b have a construction such that they not are in direct contact with the electric components of the electric control unit 23 mounted in the inner space of the compact modular unit 4. Hall-effect sensors or magnetic sensors may be used as electric components in the electric control unit 23, which sense the position of the push buttons 29a, b.

The respective tubes 8a, b, 11a, b, 12, 13, 15a, b, are connected to the compact modular unit 4 at an end part. In order to enable a simple and releasable connection of the tubes, connection means in the form of a plurality of nipples 30-37 are arranged on the side walls 28c, d of the casing of the compact modular unit 4. A first nipple 30 enables a connection of the first milk tube 8a and a second nipple 31 enables a connection of the second milk tube 8b. A third nipple 32 and a fourth nipple 33 enable a connection of the respective long pulse tubes 11a, b. A fifth nipple 34 enables a releasable connection of the vacuum tube 12 and a sixth nipple 35 enables a connection of the fresh air tube 13. A seventh nipple 36 enables a connection of the second cleaning liquid tube 15b and an eighth nipple 37 enables a connection of an the first cleaning liquid tube 15a.

FIG. 4 discloses schematically the components and parts, which are mounted in the inner space of the compact modular unit 4. One of said components is the milk meter 9, which is mounted in the inner space together with a short tubular element 38. The tubular element 38 comprises here the nipples 30, 31. Alternatively, the tubular element 38 and the nipples may be separate parts connected in a suitable manner. The milk meter 9 and the tubular element 38 constitute a connection between the first milk tube 8a and the second milk tube 8b. The milk meter 9 may have a conventional construction. Consequently, the milk meter 9 may comprise a flow sensor or use infrared light in order to measure the milk flow through the compact modular unit 4. A further component is the pulsator 10, which together with two short tubular elements 39, 40, is mounted in the inner space of the compact modular unit 4. The tubular element 39 comprises the nipples 32, 34 and the tubular element 40 comprises the nipple 33. However, the tubular element 40 and the nipple 35 are mounted at a distance from each other. Thereby, the whole inner space of the compact modular unit 4 will be filled with fresh air, when the nipple 35 is connected to the fresh air tube 13. A further component is the control valve 17, which together with a short tubular element 41 is mounted in the inner space of the compact modular unit 4. The tubular element 41 comprises the nipples 36, 37. The control valve 17 and the tubular element 41 constitute a connection between the first cleaning liquid tube 15a and the second cleaning liquid tube 15b.

The electric control unit 23 is a further component, which is mounted in the inner space of the compact modular unit 4. In order to control the other components in the inner space, a number of short electric signal lines 42, 43, 44, 45, 46 or the like are arranged between the electric control unit 23 and the respective components 9, 10, and 17. An electric signal line 42 is arranged to transmit signals between the milk meter 9 and the electric control unit 23. Thereby, the electric control unit receives information about the milk flow through the milk meter 9. An electric signal line 43 is arranged to transmit signals from the electric control unit 23 to the pulsator 10 for controlling the pulsating vacuums, which are supplied to the respective pairs of teatcups 7. An electric signal line 44 is arranged to transmit signals from the electric control unit 23 for controlling the opening and the closing of the control valve 17. An electric signal line 45 extends from the electric control unit 23 to the indicating lamps 27 for the activation of said lamps 27. Finally, an electric signal line 46 or a corresponding electric component is used, which transmits information to the electric control unit 23 about the position of the push buttons 29a, b.

The compact modular unit 4 comprises a number of electric coupling members 47, 48, 49. A first electric coupling member 47 is arranged to enable a releasable connection of the electric signal line 25 to the compact modular unit 4. A second electric coupling member 48 is arranged to enable a releasable connection of the electric cable 26 to the compact modular unit 4. A third electric coupling member 49 is arranged to enable a releasable connection of the electric signal line 24 from the remover 21 to the compact modular unit 4.

The rear wall 28e of the casing is in a mounted state in contact with the wall surface 2a of the pit. The other walls of the casing 28a-d are in contact with surrounding air. Therefore, said other wall surfaces of the casing 28a-d are more exposed to damage and rapid temperature variations than the rear wall 28e. Rapid temperature variations may be arisen if, for example, cold water is splashed on the compact modular unit 4. Therefore, it is an advantage if all the components 9, 10, 17, 23 inside the inner space of the compact modular unit 4 are mounted against the rear wall surface of the casing 28e. With such a mounting, it is possible to accomplish an air gap in the inner space between the components 9, 10, 17, 23 and the inner surfaces of the exposed walls 28a-d. Such an air gap provides a heat insulation between the components 9,,10, 17, 23 and the exposed walls 28a-d of the compact modular unit 4. Furthermore, said air gap results in that the components 9, 10, 17, 23 are not in direct contact with the inner surfaces of the exposed walls 28a-d. The risk that damages on the components 9, 10, 17, 23 are arisen due to external forces acting on the outer surfaces of the 28a-d is in that way reduced. In order to receive access to the components 9, 10, 17, 23 during services, at least one of the wall 28a-d of the casing is openable or dismountable. Preferably, at least the front wall 28a, b of the casing is openable.

When a cow enters the milking stall, the electric control unit 23 receives information from the main control system, via the electric signal line 25 about the identity of the cow. Furthermore, the electric control unit 23 may receive information when possible gates to the milking stall is closed such that it is possible to start the milking process. An indicating lamp 27 on the compact modular unit 4 can indicate when it is possible to start the milking process. The milking process comprises initially the step that the milking operator cleans the teats of the cow. After that, the milking operator attaches the teatcups 7 to the teats of the cow. The milking operator depresses the push button 29a such that the electric control unit 23 activates the pulsator 10. The milking process starts and the electric control unit 23 controls the pulsator 10 such that it supplies a pulsating vacuum with a desired frequency to the pulsating chambers of the teatcups 7a. The frequency of the pulsating vacuum may be varied during different periods of the milking process. The milk meter 9 measures the milk flow through the milk tubes 8a, b during the milking process. The electric control unit 23 receives information from the milk meter 9 about the value of milk flow. The electric control unit 23 calculates the total milk quantity from each milking process and transmits this information, via the electric signal line 25, to the main control system.

When the milking process is finished, the electric control unit 23 activates the remover 21 such that it removes the teatcups 7 from the teats. A gate to the milking stall may be open and the cow leaves the milking stall. The milking operator attaches the teatcups 7 in an upside-down position on the respective four candle-shaped plugs 19 of the washing assembly 16. The milking operator depresses the push button 29b such that the washing process is started. The electric control unit 23 regulates the control valve 17 to an open position such that a flow of cleaning liquid achieves through the cleaning liquid tubes 15a, b. The cleaning liquid flows through the manifold 18 and the respective candle-shaped plugs 19. From the candle-shaped plugs 19, the cleaning liquid is supplied to the inner surfaces of the respective teatcups 7. Thereafter, the cleaning liquid flows through the short milk tubes, the claw 6, the second cleaning liquid tube 15b, the tube element 38, the milk meter 9 and the first cleaning liquid tube 15a. The first cleaning liquid tube 15a comprises a not shown valve member or the like, which discharges the cleaning liquid flow to a collecting container or the like for used cleaning liquid. After that, it is possible to start a new milking process of another cow in the milking stall.

The environment in the pit 2 is very corrosive. In order to make it possible to mount milking components and especially electric components in the pit 2, it is a condition that the components are very well protected. The substantially hermetically encasing of the components inside the casing 28 of the compact modular unit 4 results in such a protection. Furthermore, the connection of the fresh air tube 13 to the inner space of the compact modular unit 4 guarantees that the pulsator 10 continuously has access to fresh air. Thereby, the risk that unclean air from the pit 2 is sucked into the inner space of the compact modular unit 4 is substantially eliminated. Consequently, the components mounted in the inner space of the compact modular unit 4 are placed in a very protected and clean environment. The risks, that deposits are formed on the components and that the components are corroded, are negligible. The fresh air tube 13 may be connected to a fresh air source, which may have a predetermined atmospheric humidity, temperature and pressure. Thereby, it is possible to accomplish a substantially optimal environment for the components in the inner space of the compact modular unit.

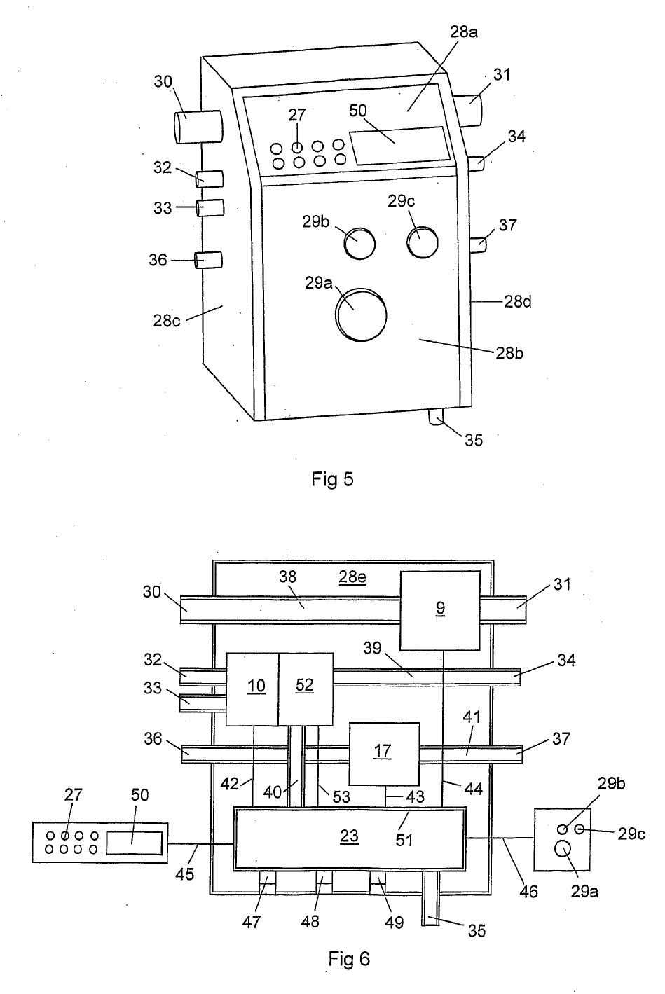

FIGS. 5 and 6 discloses an alternative embodiment of the compact modular unit 4. In this case, a component in the form of a valve arrangement 52 also is mounted in the inner space of the compact modular unit 4. The valve arrangement 52 is arranged to adjust the vacuum level to a desired value. Therefore, the control unit 23 is connected to the valve arrangement 52 via an electric signal line 53. Furthermore, the indicating means comprises eight indicating lamps 27 and one display screen 50. A third push button 29c is arranged on the front surface of the casing 28b. The third push button 29c may be used for selecting information to be disclosed on the screen in a menu system. However, the electric components are most sensitive for the corrosive environment in the pit 2 than other components 9, 10, 17, 52. Therefore, all electric components of the electric control unit 23 are here encased in a body in the form of a box 51. If damp is penetrated through the casing of the compact modular unit, the electric components are still protected from the damp inside the box 51. The box 51 may be manufactured of a transparent molded resin. In this case, fresh air is supplied to the inner space of the box 51 via the nipple 35, when it is connected to the fresh air tube 13. Furthermore, a tubular element 40 connects the box 51 with the valve arrangement 52 and the pulsator 10. Thereby, the valve arrangement 52 and the pulsator 10 have continuously access to the fresh air from the box 51. In this case, air is not sucked from the part of inner space of the compact modular unit 4 located outside the box 51. Therefore, no negative pressure is arisen in this part of the inner space in which the milk meter 9, the pulsator 10, the control valve 17 and the valve arrangement 52 are mounted. Therefore, the risk that unclean air, from the pit 2, is sucked into this part of the inner space of the compact modular unit 4 is improbable.

The use of such a compact modular unit results in several advantages. One advantage is that all components may be pre-mounted in the compact modular unit 4. Thereby, the compact modular unit with encased components may be mounted as an integrated unit in substantially all kinds of milking stalls in a very quick and simple manner. Furthermore, all components may be standardized and have a predetermined position in the inner space of the compact modular unit. Thereby, it is easy to perform services and exchange of defective component of the compact modular unit 4. Furthermore, a serviceman may be provided with a kit of standardized parts, which normally are exchanged during services. Such parts may be short tubular elements 38 and gaskets, which are in contact with milk. Also the external tubes and the electrical signal lines and cables, which are connected to the compact modular unit may be given a standardized length. In such a case, it is also very simple to mount these external components.

Consequently, services and reparations of the milking equipment in a milking stall may be performed with a relative restricted numbers of standardized components, tubes and electric cables.

Additionally, the compact modular unit comprises a casing 28, which provides a very good protection for the components 9, 10, 17, 23, 52 which are mounted in its inner space. The components 9, 10, 17, 23, 52 are here protected both from external forces, corrosive substances and impurities in the milking stall. Due to these facts, it is possible to mount the compact modular unit in a pit 2 of a milking stall below the wall surface 1 for the cows in the milking stall. Thereby, the length of the tubes and electric cables connected to the compact modular unit may be minimized. The washing assembly 16 and remover 21 may also be attached in the pit 2 by means of the first holding member 20 and the second holding member 22. Thereby, it is possible to attach and collect substantially all milking equipment in the pit 2 at a level below the floor 1 of the milking stall.

The invention is not limited to the described embodiments but may be varied and modified freely within the scope of the claims. Except the electric control unit, an arbitrary number of components in different combinations may be mounted in the inner space of the compact modular unit.

1. A compact modular unit to be mounted in a milking stall, wherein the milking stall comprises at least one pipeline system which provides an operative function in connection with a milking process of an animal in the milking stalls, the compact modular unit comprising:
a casing which defines an inner space of the compact modular unit;
an electric control unit, which is mounted in said inner space of the compact modular unit;
and indication means, which are arranged for displaying information related to the milking processes in the milking stall; and
a component of the pipeline system, which component is mounted in the inner space of the compact modular unit.

2. A compact modular unit according to claim 1, wherein the component of the pipeline system is a part of a milk pipeline system arranged to transport milk in the milking stall.

3. A compact modular unit according to claim 2, wherein component of said milk pipeline system, which is mounted in the inner space of the compact modular unit is a milk meter.

4. A compact modular unit according to claim 2, wherein the compact modular unit comprises connection means for enabling a releasable connection of at least one milk tube of the milk pipeline system to the compact modular unit.

5. A compact modular unit according to claim 1, wherein said component of the pipeline system is a part of a vacuum pipeline system arranged to supply a pulsating vacuum to a milking member which is attached to an animal during a milking process in the milking stall.

6. A compact modular unit according to claim 5, wherein the component of said vacuum pipeline system, which is mounted in said inner space of the compact modular unit, is a pulsator.

7. A compact modular unit according to claim 5, wherein the component of said vacuum pipeline system, which is mounted in said inner space of the compact modular unit, is a valve arrangement arranged to control the vacuum level supplied to the milking member.

8. A compact modular unit according to claim 5, wherein the compact modular unit further comprises connection means for enabling a releasable connection of at least one pulse tube of the vacuum pipeline system to the compact modular unit.

9. A compact modular unit according to claim 5, wherein the compact modular unit further comprises connection means for enabling a releasable connection of a vacuum tube of the vacuum pipeline system to the compact modular unit.

10. A compact modular unit according to claim 5, wherein the compact modular unit further comprises connection means for enabling a releasable connection of a fresh air tube of the vacuum pipeline system to the compact modular unit.

11. A compact modular unit according to 1, wherein the component of the pipeline system is a part of a wash pipeline system arranged to wash at least the teatcups of a milking member after a milking process is finished.

12. A compact modular unit according to claim 11, wherein the component of said wash pipeline system, which is mounted in the inner space of the compact modular unit, is a control valve.

13. A compact modular unit according to claim 11, wherein the compact modular unit further comprises connection means for enabling a releasable connection of at least one cleaning liquid tube to the compact module unit.

14. A compact modular unit according to claim 1, wherein the compact modular unit further comprises connection means for enabling a releasable connection of an electric signal line to the compact modular unit.

15. A compact modular unit according to claim 1, wherein the compact modular unit further comprises connection means for enabling a releasable connection of an electric cable to the compact modular unit, which is connected to an electric power source.

16. A compact modular unit according to claim 1, wherein said electric control unit, which is mounted in the inner space of the compact modular unit, is arranged to control a remover, which remover is arranged to remove a cluster from an animal after a milking process is finished.

17. A compact modular unit according to claim 1, wherein the compact modular unit further comprises connection means for enabling a releasable connection of an electric signal line from the remover to the compact modular unit.

18. A compact modular unit according to claim 1, wherein the casing has a construction such that said inner space substantially hermetically encases the electric control unit and said component.

19. A compact modular unit according to claim 1, wherein the compact modular unit further comprises a body which encases the electric control unit in the inner space of the compact modular unit.

20. A compact modular unit according to claim 1, wherein said compact modular unit further comprises a body which encases the electric control unit in the inner space of the compact modular unit and wherein said fresh air tube is arranged to supply fresh air to the inner space of said body.

21. A compact modular unit according to claim 1, wherein said casing includes walls having inner surfaces and outer surfaces and wherein the electric control unit is mounted in a position in the inner space of the compact modular unit at a distance from the inner surfaces of the walls of the casing, which outer surfaces are in contact with the surrounding air in the milking stall.

22. A compact modular unit according to claim 1, wherein said indicating means comprises at least one indicating lamp.

23. A compact modular unit according to claim 1, wherein said indicating means comprises an indicating screen.

24. A compact modular unit according to claim 1, wherein the compact modular unit further comprises a manual control member.

25. A compact modular unit according to claim 24, wherein said manual control member is a push button.

26. A compact modular unit according to claim 1, wherein said component and the electric control unit are pre-mounted in the inner space of the compact modular unit before the compact modular unit is mounted in the milking stall.

27. A milking stall, comprising a compact modular unit according to any one of the preceding claim 1.

28. A milking stall as set forth in claim 27, wherein the milking stall comprises a floor surface configured to permit an animal to stand thereon during a milking process and a pit located adjacent to said floor surface wherein the compact modular unit is mounted in the pit at a level below the floor surface of the milking stall.

29. A milking stall according to claim 28, wherein the compact modular unit is mounted against a wall surface of the pit.

30. A milking stall according to claim 29, wherein the pit comprises an overhang at an upper edge, wherein the compact modular unit is mounted in a position under said overhang.
